(19) United States
(12) Patent Application Publication
(10) Pub. No.: US 2005/0052927 A1
(43) Pub. Date: Mar. 10, 2005

(54) Method and apparatus for assigning addresses to alarm system devices

(75) Inventor: Mark P. Barrieau, Baldwinville, MA (US)

Correspondence Address: IP LEGAL DEPARTMENT;TYCO FIRE & SECURITY SERVICES, ONE TOWN CENTER ROAD, BOCA RATON, FL, 33486, US

(73) Assignee: SimplexGrinnell LP, Westminster, MA (US)

(21) Appl. No.: 10/936,211

(22) Filed: Sep. 8, 2004

Related U.S. Application Data
(60) Provisional application No. 60/501,333, filed on Sep. 8, 2003.

(51) Int. Cl. G11C 7/00

(52) U.S. Cl. 365/222

(57) ABSTRACT

An apparatus, system and method for quickly and simply providing non-duplicative addresses for addressable devices on a communication channel or network. The system contains at least one system controller communicating with at least one addressable device on at least one communications channel or network. Preset address elements configured in a mating connector arrangment or as an adhesive label provide unique addresses to each of the addressable devices. The preset address elements may use digital or analog circuit techniques to encode unique addresses that are subsequently read and stored by the addressable devices. When installed, the preset address elements also provide visual indications of the device addresses.

### CROSS-REFERENCE TO RELATED APPLICATION

The present application claims the benefit of the filing date of co-pending U.S. Provisional Application Ser. No. 60/501,333 filed Sep. 8, 2003, the teachings of which are incorporated herein by reference.

### TECHNICAL FIELD

The present application is generally related to networks, and more particularly is related to addressable devices requiring unique addresses on a network or communication channel.

### BACKGROUND

In typical networked systems, such as a fire or security alarm system, many types of sensors, detectors, lights, strobes, sounders and other associated devices may be located throughout different areas as part of the system. Groups of these devices are often wired together along communication lines. A group of such devices is often referred to as a “line of devices.” Many lines of devices may connect to a control panel that controls the overall operation of the system. A line of devices may be associated with a certain zone of a building and/or a certain type of device. For example, one floor of a multi-story building may have all of its smoke detectors wired together on a line that connects to the control panel.

Each device on a line may be individually addressed from the control panel. Individual addressing of devices allows a single device to indicate an alarm condition at a specific location on a line, provides selective operation of specific devices, and can also be useful for alarm system fault diagnosis and/or individual device testing. Unique device addresses may be set in each device, for example, electronically by signal download from an external programming tool or by manually configuring DIP switches, rotary switches, or jumpers internal to the device. The address of a device is typically visually identified after the address is set, for example, by affixing a label showing the address to the device. During the installation of many devices, however, an installer may accidentally configure the same address in more than one device. The problem of duplicate addressing may cause failures in device communications resulting in incorrect operation of the system. Also, separate efforts associated with assigning a device address and labeling the address on the device are cumbersome and inefficient.

There is, therefore, a need for an efficient system and method for reliably assigning addresses to addressable system devices.

### BRIEF DESCRIPTION OF THE DRAWINGS

Many aspects of the invention can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIG. 1 is a schematic illustration of a system consistent with the invention including a system controller having a plurality of channels and devices.

FIG. 2 is an exploded view of an exemplary preset address element and an associated mating connector disposed on an addressable device consistent with the present the invention.

FIG. 3 illustrates an exemplary embodiment of a fused conductor in the preset address element shown in FIG. 2.

FIG. 4 is a representative schematic diagram showing an exemplary electrical configuration of a preset address element consistent with the present invention.

FIG. 5 illustrates a preset address element as shown in FIG. 2 configured with one example of a preset address consistent with the present invention.

FIG. 6 illustrates another exemplary embodiment of a preset address element consistent with the present invention.

FIG. 7 illustrates an exemplary arrangement of preset address elements packaged on a packaging stick consistent with the present invention.

FIG. 8 is a front view of another exemplary preset address element consistent with the present invention.

FIG. 9 is a side view of the preset address element shown in FIG. 8.

FIG. 10 is a rear view of the preset address element shown in FIG. 8.

FIG. 11 is a rear view of another exemplary embodiment of a preset address element consistent with the present invention.

FIG. 12 is a rear view of another exemplary embodiment of a preset address element consistent with the present invention.

FIG. 13 illustrates an exemplary addressable device configuration including electrical contacts consistent with the present invention.

FIG. 14 illustrates a preset address element aligned with electrical contacts on the addressable device configuration of FIG. 13.

FIG. 15 is a front view of one exemplary embodiment of a sheet of preset address elements consistent with the present invention.

FIG. 16 is a flow chart of exemplary methods for assigning addresses to addressable devices consistent with the invention.

### DETAILED DESCRIPTION

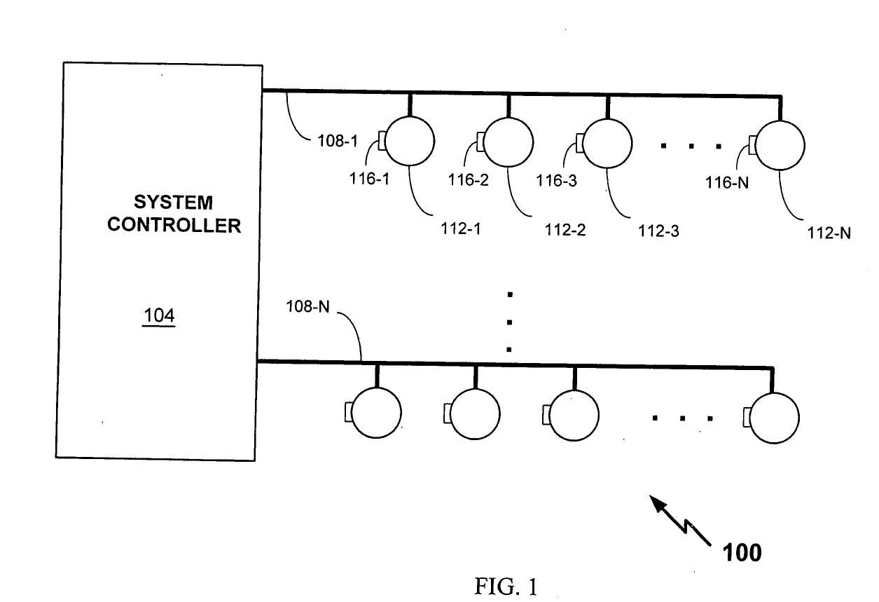

FIG. 1 illustrates an exemplary system 100 consistent with the present invention including a system controller 104. For clarity and ease of explanation, the system is depicted with only one system controller 104. Those of ordinary skill in the art will recognize, however, that a system consistent with the invention may include a plurality of system controllers configured for controlling a wide variety of addressable devices.

The system controller 104 may be coupled to one or more communication channels 108-1 . . . 108-N to provide electrical communication between the system controller 104 and a plurality of uniquely addressable devices, e.g. devices 112-1, 112-2, 112-3 . . . 112-N, coupled to the communication channels. The addressable devices 112-1, 112-2, 112-3 . . . 112-N may include, but are not limited to, fire and security alarms, sensors, detectors, lights, strobes, sounders, and other devices requiring addressable capability on a communications channel or network. In one embodiment, each communication channel 108 may communicate with up to two hundred fifty (250) uniquely addressable devices 112.

Each addressable device 112-1, 112-2, 112-3 . . . 112-N includes an associated preset address element 116-1, 116-2, 116-3 . . . 116-N, respectively. Each address element 116 may establish a device address for its associated device 112 and may provide a visual indication of the device address. The system controller 104 may communicate with the addressable devices 112 through the communication channels 108 using a variety of known communications protocols including, for example, but not limited to, TCP/IP, or proprietary communications protocols.

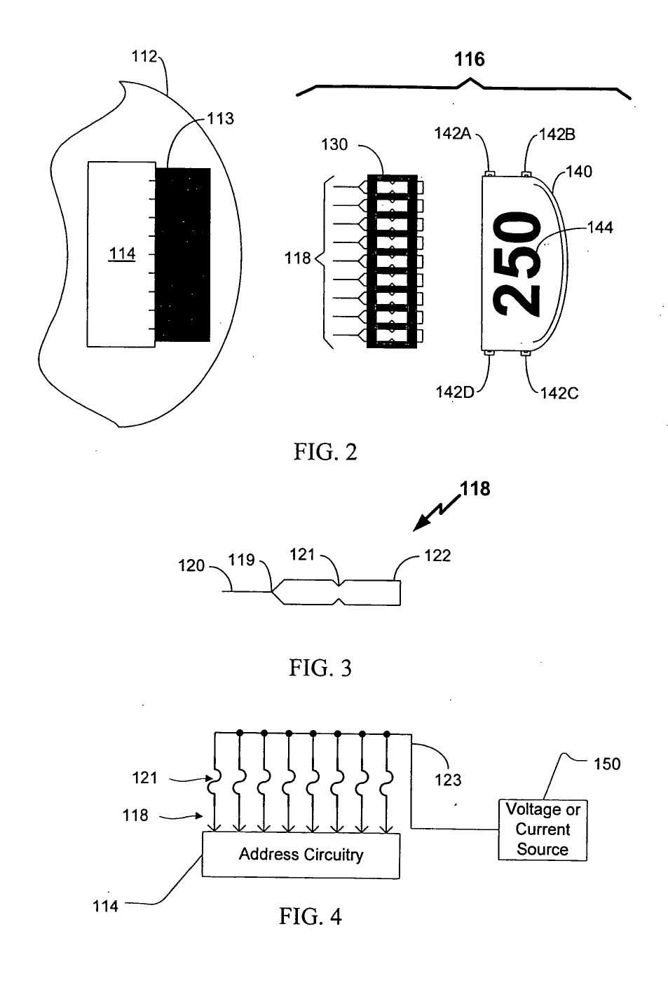

FIG. 2 is an exploded view of an exemplary preset address element 116 and an associated mating connector 113 on an addressable device 112 consistent with the present invention. The mating connector 113 may be configured, for example, as single in-line connector mounted on the addressable device 112. In addition to providing a mechanical connection, the mating connector 113 provides electrical communication between the preset address element 116 and associated address circuitry 114 on the addressable device 112.

As shown, the preset address element 116 may include a plurality of fused conductors 118 assembled on a frame assembly 130 constructed from electrically insulating material including, for example, but not limited to, nylon, polyester, and plastic. The number and configuration of the fused connectors 118 may determine the range of addresses available for the preset address element 116. A cap 140 may be attached to the frame assembly 130 by, for example, latches 142A-D engaged with the frame assembly 130. Those of ordinary skill in the art will recognize other methods of permanently or removably securing the cap 140 to the frame assembly 130 may be used. The cap 140 may display a base-10 numeral 144, as an example, the numeral two hundred fifty (250), corresponding to an address preset into the preset address element 116. In addition to identifying the preset address of the preset address element 116, the cap 140 may provide a visual indication of the address of an addressable device 112 allowing easy identification of the device by service or emergency personnel.

FIG. 3 illustrates an exemplary embodiment of a fused conductor 118. As shown, each fused conductor 118 may include a first end 119 forming a contact pin 120 for making electrical connection with an associated contact on the matting connector 113, a reduced section forming a fused portion 121, and a second end 122 for forming a common electrical connection among the plurality of fused conductors 118. A person of ordinary skill in the art will appreciate that other types of fused conductors may be formed. For example, fused conductors may be formed by varying wire gauges or conductively loaded insulating materials.

Each fused conductor 118 may be “opened” by passing an electrical current higher than the normal operating current through the fused conductor 118. The electrical current must be of sufficient magnitude to overheat the fused portion 121 of the fused conductor 118, thereby causing the fused portion 121 to melt, or “blow,” resulting in an open electrical circuit from one end of the conductor to an opposite end of the conductor. By selectively opening/blowing fused conductors 118, a code corresponding to an address may be preset in the preset address element 116.

The address associated with the address element 116 may be read by the addressable device 112 and established as the device address of the addressable device 112, e.g. upon installation of the address element in the device or upon power-up of the device. Those of ordinary skill in the art will recognize that a variety of electrical configurations may be provided to enable reading of an encoded address in an address element 116 by an addressable device 112. FIG. 4, for example, is a schematic diagram showing one exemplary electrical configuration of the fused conductors 118 in the preset address element 116. As shown, a source of voltage or current 150 provided by the addressable device 112 may be connected to a common conductor 123 coupled to each of the fused conductors. The common conductor may be a separate conductor or may be one of the fused conductors. Opposite ends of the fused conductors may be coupled to the address circuitry 114 of the addressable device, which may interpret current through, or voltage on, each of the fused conductors as representative of an address associated with the address element 116 and establish that address as the address of the device 112.

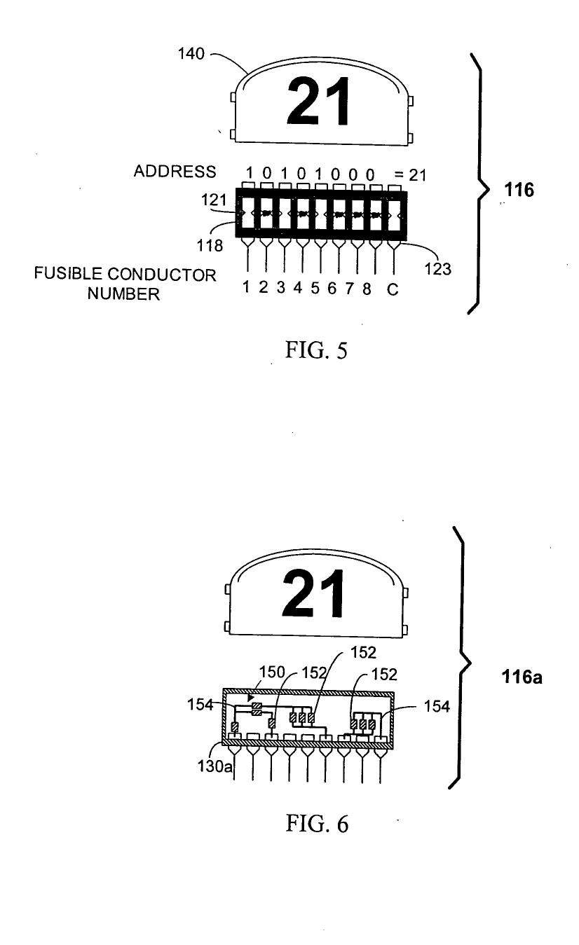

FIG. 5 illustrates an exemplary preset address element 116 configured with a preset address. Before installing the preset address element 116 in the addressable device 112, an address of twenty-one (21) may be set by blowing the fused portions 121 of all the fused conductors 118 as described above, except the first, third, and fifth fused conductors 118, as shown. After installation, the address circuitry 114 on the addressable device 112 may supply a source of voltage or current to the common fused conductor 123. The circuitry on the addressable device 112 may then read a binary address of 1010100 equal to a base-10 address of 21. The cap 140 may provide a visual indication of the base-10 address of 21. Those of ordinary skill in the art will recognize that there are many other digital code schemes that may be implemented in this way.

In an alternative embodiment, an address may be encoded on a preset address element 116a using analog circuit techniques. As illustrated in FIG. 6, for example, a conductive network 150 including conductive traces 154 and electrical elements 152 including, for example, but not limited to, resistors, capacitors, and/or inductors, may be disposed on the frame assembly 130 of the preset address element 116. When the conductive network 150 is excited by a voltage or current generated by electrical circuitry disposed on the addressable device 112, a measured electrical parameter including, for example, but not limited to, resistance, capacitance, and/or inductance, of the conductive network 150 disposed on the preset address element 116 may be translated as an address for the addressable device 112. The conductive network 150 may be formed using processes or techniques including, for example, but not limited to, printed circuit technologies, thick film process, thin film processes, and/or discrete device technology.

A person of ordinary skill in the art will appreciate that other means may be used to encode an address on the preset address element, and for the addressable device to read and store the address from the preset address element. Other means may include, but are not limited to, a Wigand wire disposed to form an address code that may be read by electrical circuitry disposed on the addressable device, Hall-effect sensors disposed in the addressable device that may read an address code formed by magnets disposed in the preset address element, and optical encoding techniques.

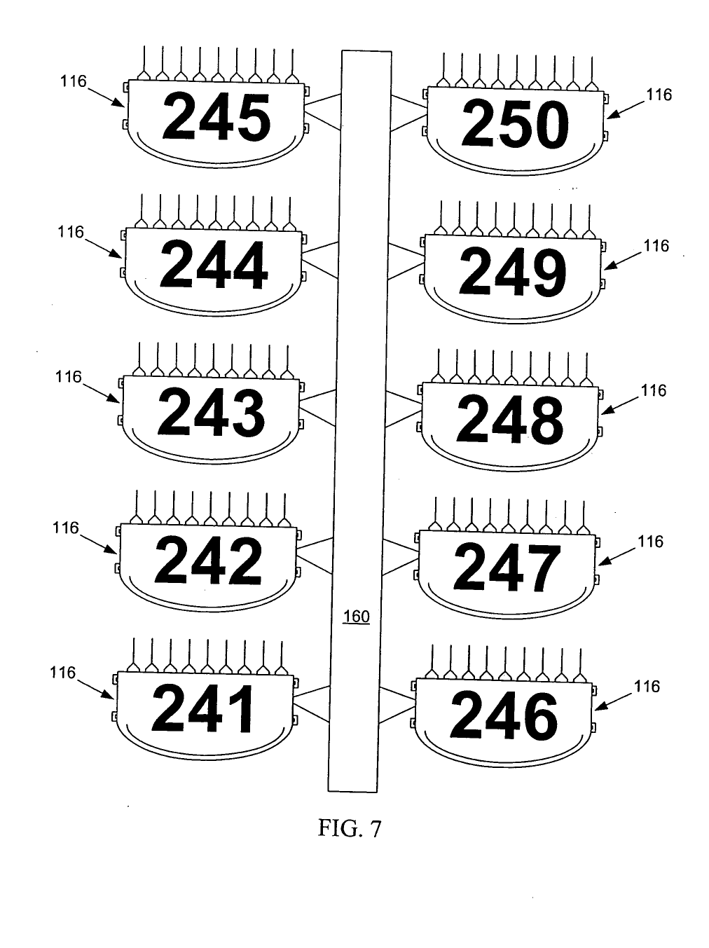

The preset address elements 116 may be packaged on packaging “sticks” 160 as shown in FIG. 7, with a plurality of preset address elements 116, for example, ten (10) unique preset address elements 116 attached to each packaging stick 160. The packaging sticks 160 may be fabricated as part of the frame assemblies 130 or as part of the caps 140. To assign the address to the addressable device 112, the preset address element 116 may be removed from the packaging stick 160 and inserted into the mating connector 113 on the addressable device 112. When power is applied to the addressable device 112, address circuitry 114 disposed on the addressable device 112 may read and store the address of the preset address element 116, thereby assigning the encoded address of the preset address element 116 as the device address of the addressable device 112.

In one embodiment, each preset address element 116 may be preset to a unique address starting at one (1) and ending at two hundred fifty (250). Associated caps 140 displaying base-10 address numerals 144 starting at one (1) and ending at two hundred fifty (250) may be provided. The address numerals on each cap may thus correspond to a preset address on an associated element 116. The cap associated with each address element 116 may be installed on the associated frame assembly 130. Since each series of preset address elements 116 contains two hundred fifty (250) unique preset addresses, and each addressable device 112 obtains an address from a preset address element 116, each addressable device 112 is guaranteed its own unique address, thereby eliminating the possibility of duplicate address assignments. Further, the address of the addressable device 112 is easily visually identifiable from the base-10 numeral 144 on the cap 140 after the preset address element 116 is installed.

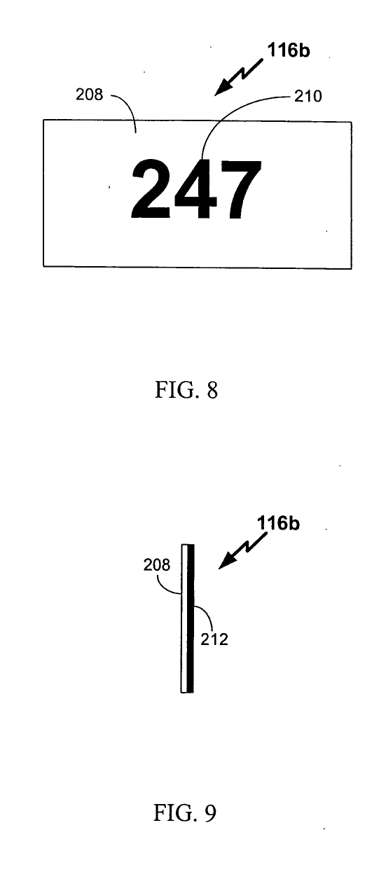

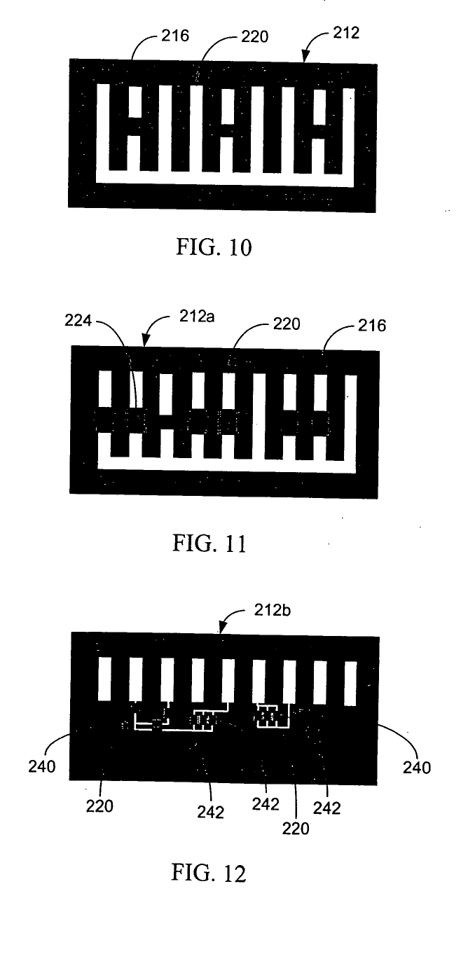

FIGS. 8-10 illustrate another embodiment of a preset address element 116b consistent with the present invention. The address element 116b may include a printed side 208 and an adhesive side 212, and may be constructed from an insulating material including, for example, but not limited to, a plastic. The printed side 208 of the address element 116b may display a base-10 numeral 210 corresponding to a preset address of the preset address element 116b. The adhesive side 212 of the address element may include an adhesive 216, e.g. a pressure sensitive adhesive and conductive traces 220. The conductive traces may be fabricated using thick film or thin film process technology, or by other suitable printed circuit technologies. The pressure sensitive adhesive 216 may be disposed on the adhesive side 212 of the address element 11 6b in the areas not occupied by electrical circuitry, e.g. the conductive traces 220.

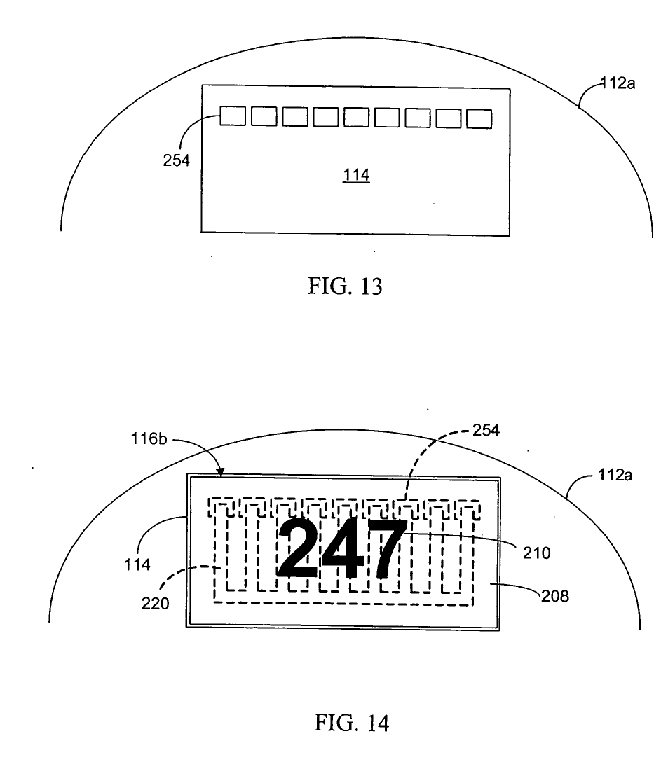

The conductive traces may be configured to provide electrical communication with an addressable device 112 when the adhesive side 212 of the address element is affixed to the addressable device 112, e.g. as shown in FIG. 14. The number and configuration of the conductive traces 220 may establish an address for the addressable device. For example, a unique address may be encoded for a device by removing, interrupting or modifying one or more of the conductive traces 220.

Those of ordinary skill in the art will recognize that the adhesive side may be provided in a variety of configurations for establishing a preset address for the address element 116b. FIG. 11, for example, illustrates an adhesive side 212a including electrical components for establishing an address. The electrical components 224 may include, resistors, capacitors and/or inductors, and may be fabricated using thick film or thin film process technology, or by other suitable printed circuit technologies. Alternatively, the electrical components 224 may be discrete devices including, for example, but not limited to, surface mount devices. When using electrical components 224, one or more of the conductive traces 220 may be modified, e.g. interrupted, to provide locations on the adhesive side for receiving the electrical components 224. Those of ordinary skill in the art will recognize conductive trace configurations and/or combinations of electrical components 224 may be used to produce unique address codes for the preset address elements 116b.

Alternatively, an address may be encoded on the preset address element 200 using analog circuit techniques. FIG. 12 shows and exemplary embodiment 212b of an address element adhesive side including conductive networks 240. The conductive networks include conductive traces 220 and electrical components 242 including, for example, but not limited to resistors, capacitors, and inductors. When the conductive network 240 is excited by a voltage or current generated by address circuitry 114 disposed on an addressable device 112, a measured electrical parameter including, for example, but not limited to, resistance, capacitance, or inductance, of the conductive networks 240 may be translated as an address for the addressable device 112. The conductive networks 240 may be formed using processes or techniques including, for example, but not limited to, printed circuit technologies, thick film process, thin film processes, and/or discrete device technology.

As illustrated in FIG. 13, electrically conductive contacts 254 may be disposed on a surface of an addressable device 112a to provide an interface to the address circuitry 114 disposed therein. To establish an address for the addressable device 112a, electrically conductive traces 220 on a preset address element 116b may be aligned with corresponding electrical contacts 254, as shown for example in FIG. 14, to provide electrical communication between the conductive traces 220 and the addressable device 250. The address circuitry 114 may interpret the configuration of the conductive traces 220 to establish the preset address of the address element as the address for the addressable device. The numeral 210 on the printed side 208 of the address element may provide a visual indication of the address established for the device 212a by the address element 116b. Although the illustrated embodiment shows a particular arrangement of contacts 254 mating with conductive traces, a person of ordinary skill in the art will appreciate that other contact arrangements are possible.

A person of ordinary skill in the art will appreciate that other means may be used to encode an address on the preset address element, and for the addressable device to read and store the address from the preset address element. Other means may include, but are not limited to, Wigand wire disposed to form a magnetic address code that may be read by electrical circuitry disposed on the addressable device, Hall-effect sensors disposed in the addressable device that may read an address code formed by magnets disposed in the preset address element, and optical encoding techniques.

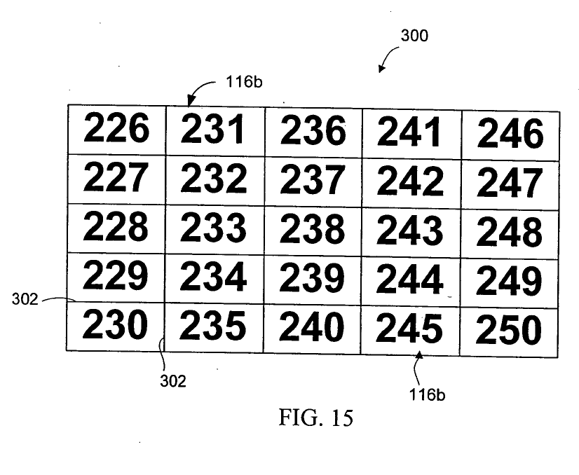

In one exemplary embodiment, two hundred fifty (250) unique addresses (1 through 250) may be encoded on preset address elements 116b. As illustrated in FIGS. 15, a plurality of preset address elements 116b, each configured for establishing a different address for an addressable device, may be disposed on a release sheet 300. The illustrated exemplary release sheet 300, for example, holds twenty-five (25) preset address elements 116b. The individual address elements 116b may be separated on the release sheet by, for example, perforations 302, allowing the address elements to be removed from the sheet for application to an associated addressable device. When affixed to an addressable device, each address element 116b establishes a unique address for the addressable device and provides a visual indication of the address allowing easy identification of the device by service or emergency personnel.

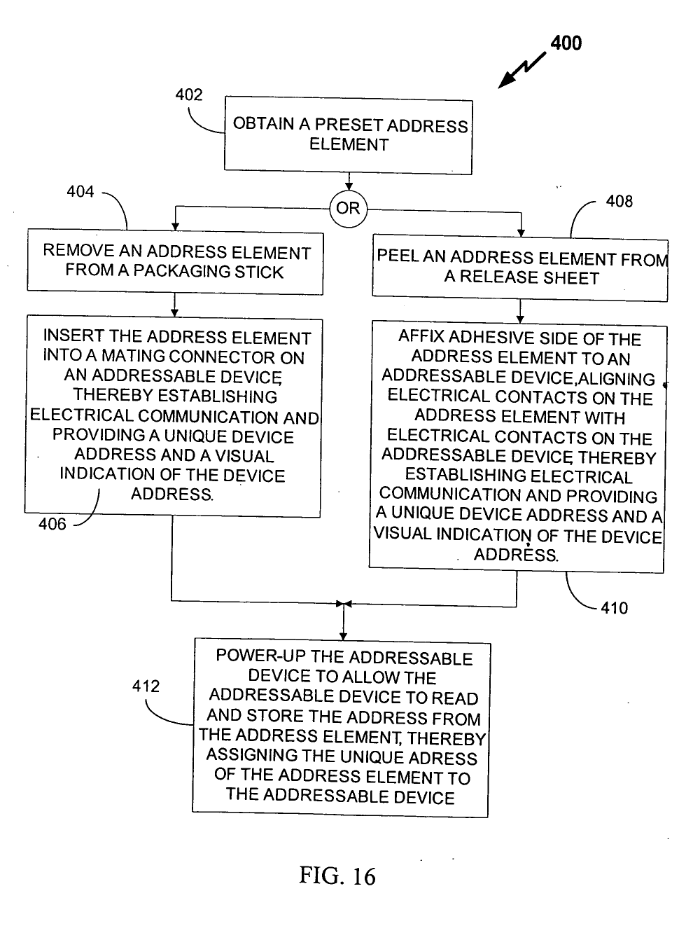

FIG. 16 is a flow chart outlining an embodiment 400 of a system consistent with the present invention. As shown, a preset address element may be obtained 402 for a system that may include a system controller and at least one addressable device. In one embodiment, the preset address element may be removed 404 from a packaging stick and inserted 406 into a mating connector on the addressable device to establish electrical communication between the addressable device and the preset address element and to provide a visual indication of the device address. In another embodiment, the preset address element may be removed 408 from a release sheet and adhesively affixed 410 to the addressable device, aligning electrical contacts on the preset address element with electrical contacts on the addressable device to establish electrical communication between the preset address element and the addressable device and to provide a visual indication of the device address. In either embodiment, the addressable device may be powered-up 414 to enable the addressable device to read and store the unique address encoded on the preset address element, thereby assigning the unique address of the preset address element as the address of the addressable device.

Embodiments of the present invention provide an apparatus, system and method for quickly and simply providing non-duplicative addresses, and visual indications of the addresses, for addressable devices on a communications channel or network. Briefly described, in architecture, one embodiment of the system, among others, can be implemented as follows. The system contains at least one system controller communicating with a plurality of addressable devices on at least one communications channel or network. Preset address elements configured in a mating connector arrangement or as an adhesive label provide unique addresses to each of the addressable devices. The preset address elements may use digital or analog circuit techniques to encode unique addresses that are subsequently read and stored by the addressable devices after the address elements are installed. The preset address elements may also provide visual indications of the device addresses.

The present invention can also be viewed as providing methods for supplying non-duplicative addresses and visual indications of the addresses for addressable devices. One embodiment of such a method, among others, can be broadly summarized as: installing a system having a system controller and addressable devices; obtaining preset address elements; installing one preset address element in each addressable device; and powering-up the system to enable the addressable devices to read and store the unique addresses encoded on the preset address elements.

Other systems, methods, features, and advantages of the present invention will be or will become apparent to one with skill in the art upon examination of the following drawings and detailed description. It is intended that all such additional systems, methods, features, and advantages be included within this description, be within the scope of the present invention, and be protected by the accompanying claims.

The above-described embodiments of the present invention are merely possible examples of implementations, merely set forth for a clear understanding of the principles of the invention. Many variations and modifications may be made to the above-described embodiment(s) of the invention without departing substantially from the spirit and principles of the invention. All such modifications and variations are intended to be included herein within the scope of this disclosure and the present invention and protected by the following claims.

1. A system comprising:
at least one system controller;
at least one communication channel coupled to said at least one system controller;
at least one addressable device coupled to said at least one communication channel; and
at least one preset address element, each preset address element comprising a different associated encoded address, each of said addressable devices being configured to receive one of said preset address elements to establish one of said encoded addresses as a device address for said addressable device, each said addressable device thereby being assigned a different associated device address for communication with said system controller through said communication channel.

2. The system of claim 1, wherein at least one of said addressable devices comprises a connector configured to mate with said one of said preset address elements for electrically coupling said one of said preset address elements thereto.

3. The system of claim 1, wherein at least one of said preset address elements comprises a plurality of fused conductors selectively configured to conduct electricity in a predetermined pattern to establish at least a portion of said encoded address.

4. The system of claim 3, wherein said fused conductors are coupled to a frame assembly.

5. The system of claim 4, said system further comprising a cap coupled to said frame assembly, said cap comprising an address identifier providing a visual indication of said encoded address.

6. The system of claim 1, wherein at least one of said preset address elements comprises a conductive network, at least one electrical parameter of said conductive network establishing at least a portion of said encoded address.

7. The system of claim 6, wherein said conductive network comprises at least one discrete electrical component selected from the group consisting of: a resistor, a capacitor and an inductor.

8. The system of claim 6, wherein said conductive network is disposed on a frame assembly.

9. The system of claim 8, said system further comprising a cap coupled to said frame assembly, said cap comprising an address identifier providing a visual indication of said encoded address.

10. The system of claim 1, wherein at least one of said addressable devices comprises a plurality of electrical contacts on a surface thereof, said electrical contacts being positioned to align with associated contacts on said one of said preset address elements.

11. The system of claim 1, wherein at least one of said preset address elements comprises:
a label comprising a first side and a second side;
a plurality of conductive traces disposed on said first side of said label, said conductive traces being configured to establish at least a portion of said encoded address; and
an address identifier on said second side of said label providing a visual indication of said encoded address.

12. The system of claim 11, wherein said first side of said label further comprises an adhesive for affixing said preset address element to said addressable device.

13. The system of claim 12, wherein the adhesive is pressure-sensitive adhesive.

14. The system of claim 11, wherein said at least one of said preset address elements further comprises at least one discrete electrical component coupled to at least one of said conductive traces.

15. The system of claim 11, wherein at least one of said addressable devices comprises a plurality of electrical contacts on a surface thereof, said electrical contacts being positioned to align with associated ones of said conductive traces.

16. A preset address element, comprising:
a frame assembly;
a plurality of fused conductors coupled to said frame assembly, said fused conductors being configured to conduct electricity in a predetermined pattern to establish an encoded address; and
a cap coupled to said frame assembly, said cap comprising an address identifier providing a visual indication of said encoded address.

17. The preset address element of claim 16, wherein said frame assembly is constructed from material selected from the group consisting of plastic, nylon, and polyester.

18. The preset address element of claim 16, wherein said cap is fixedly attached to said frame assembly by a plurality of latches.

19. A preset address element, comprising:
a frame assembly;
a conductive network disposed one the frame assembly, at least one electrical parameter of the conductive network establishing an encoded address; and
a cap coupled to said frame assembly, said cap comprising an address identifier providing a visual indication of said encoded address.

20. The preset address element of claim 19, wherein said conductive network comprises at least one discrete electrical component selected from the group consisting of: a resistor, a capacitor and an inductor.

21. The preset address element of claim 19, wherein said cap is fixedly attached to said frame assembly by a plurality of latches.

22. A preset address element comprising:
a label comprising a first side and a second side;
a plurality of conductive traces disposed on said first side of said label, said conductive traces being configured to establish an encoded address; and
an address identifier on said second side of said label providing a visual indication of said encoded address.

23. The preset address element of claim 22, wherein said first side of said label further comprises an adhesive for affixing said preset address element to an addressable device.

24. The preset address element of claim 23, wherein the adhesive is pressure-sensitive adhesive.

25. The preset address element of claim 23, said address element further comprising at least one discrete electrical component coupled to at least one of said conductive traces.

26. A method of providing a unique device addresses for each of a plurality addressable devices on a communication channel or network, said method comprising:
providing a plurality of preset address elements, each of said preset address elements comprising a different associated encoded address and an address identifier providing a visual indication of said associated encoded address;
installing each of said preset address elements on an associated one of said addressable devices.
powering-up said addressable devices, thereby enabling each addressable device to establish one of said different associated encoded addresses as an associated device address.

27. The method of claim 26, wherein at least one of said preset address elements is installed on an associated one of said addressable devices by inserting said at least one of said preset address elements into a mating connector on said associated one of said addressable devices.

28. The method of claim 26, wherein at least one of said preset address elements is installed on an associated one of said addressable devices by adhesively affixing said at least one of said preset address elements to said associated one of said addressable devices.

29. The method of claim 26, wherein said preset address elements are provided in a sheet, and wherein said preset address elements are removed from said sheet prior to said installing each of said preset address elements on an associated one of said addressable devices.
